(19) United States
(12) Patent Application Publication
(10) Pub. No.: US 2007/0080731 A1
(43) Pub. Date: Apr. 12, 2007

(54) Duty cycle corrector

(76) Inventors: Jung Pill Kim, Cary, NC (US); Alessandro Minzoni, Morrisville, NC (US); Joonho Kim, Cary, NC (US)

Correspondence Address: DICKE, BILLIG & CZAJA, P.L.L.C., FIFTH STREET TOWERS, 100 SOUTH FIFTH STREET, SUITE 2250, MINNEAPOLIS, MN, 55402, US

(21) Appl. No.: 11/247,538

(22) Filed: Oct. 11, 2005

(51) Int. Cl. H03K 3/017

(52) U.S. Cl. 327/175

(57) ABSTRACT

A duty cycle corrector includes a first controllable delay configured to delay a first signal to provide a second signal, a second controllable delay configured to delay the second signal to provide a third signal, a first fixed delay configured to delay the second signal to provide a fourth signal, a second fixed delay configured to delay the first signal to provide a fifth signal, and a circuit configured to adjust the first controllable delay and the second controllable delay to phase lock the third signal to the fifth signal.

### BACKGROUND

Many digital circuits receive a clock signal to operate. One type of circuit that receives a clock signal to operate is a memory circuit, such as a dynamic random access memory (DRAM), synchronous dynamic random access memory (SDRAM), or double data rate synchronous dynamic random access memory (DDR-SDRAM). In a memory circuit operating at high frequencies, it is important to have a clock signal that has about a 50% duty cycle. This provides the memory circuit with approximately an equal amount of time on the high level phase and on the low level phase for transferring data into and out of the memory circuit, such as latching rising edge data and latching falling edge data out of the memory circuit.

Often, a clock signal is provided by an oscillator, such as a crystal oscillator, and clock circuitry. The oscillator and clock circuitry may provide a clock signal that does not have a 50% duty cycle. For example, the clock signal may have a 45% duty cycle, where the high level phase is 45% of one clock cycle and the low level phase is the remaining 55% of the clock cycle. A duty cycle corrector receives the clock signal and corrects or changes the duty cycle of the clock signal to provide clock signals with transitions separated by substantially one-half of a clock cycle.

One type of duty cycle corrector provides an internal clock signal and an inverted internal clock signal based on an external clock signal. Typically, the duty cycle corrector is phase locked within one clock cycle at low clock frequencies. Due to intrinsic delays within the duty cycle corrector, the duty cycle corrector may not be phase locked within one clock cycle at high clock frequencies. If the duty cycle corrector is not phase locked within one clock cycle, the duty cycle corrector may fail. Therefore, the high speed operation of the duty cycle corrector is limited.

### SUMMARY

One embodiment of the present invention provides a duty cycle corrector. The duty cycle corrector includes a first controllable delay configured to delay a first signal to provide a second signal, a second controllable delay configured to delay the second signal to provide a third signal, a first fixed delay configured to delay the second signal to provide a fourth signal, a second fixed delay configured to delay the first signal to provide a fifth signal, and a circuit configured to adjust the first controllable delay and the second controllable delay to phase lock the third signal to the fifth signal.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 is a block diagram illustrating one embodiment of an electronic system.

FIG. 2 is a block diagram illustrating one embodiment of a duty cycle corrector.

FIG. 3 is a timing diagram illustrating one embodiment of the timing of signals for the duty cycle corrector without fixed delay D1 and fixed delay D2.

FIG. 4 is a timing diagram illustrating one embodiment of the timing of signals for the duty cycle corrector with fixed delay D1 and fixed delay D2.

### DETAILED DESCRIPTION

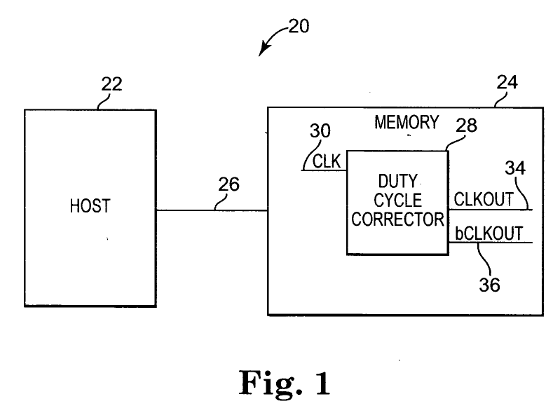

FIG. 1 is a block diagram illustrating one embodiment of an electronic system 20 according to the present invention. Electronic system 20 includes a host 22 and a memory circuit 24. Host 22 is electrically coupled to memory circuit 24 through memory communications path 26. Host 22 is any suitable electronic host, such as a computer system including a microprocessor or a microcontroller. Memory circuit 24 is any suitable memory, such as a memory that utilizes a clock signal to operate. In one embodiment, memory circuit 24 comprises a random access memory, such as a dynamic random access memory (DRAM), synchronous dynamic random access memory (SDRAM), or double data rate synchronous dynamic random access memory (DDR-SDRAM).

Memory circuit 24 includes a duty cycle corrector 28 that receives a clock (CLK) signal on CLK signal path 30. In one embodiment, duty cycle corrector 28 receives an external CLK signal on CLK signal path 30 through memory communications path 26. In other embodiments, duty cycle corrector 28 receives an external CLK signal on CLK signal path 30 from any suitable device, such as a dedicated clock circuit that is located inside or outside memory circuit 24.

Duty cycle corrector 28 provides the clock output (CLKOUT) signal on CLKOUT signal path 34 and the inverted clock output (bCLKOUT) signal on bCLKOUT signal path 36. The CLKOUT signal on CLKOUT signal path 34 is a clock signal having a duty cycle of 50%, and the bCLKOUT signal on bCLKOUT signal path 36 is a clock signal having a duty cycle of 50%. The CLKOUT signal is the inverse of the bCLKOUT signal. Duty cycle corrector 28 receives the CLK signal on CLK signal path 30, which may not have a 50% duty cycle, and provides the CLKOUT signal on CLKOUT signal path 34 and the bCLKOUT signal on bCLKOUT signal path 36, which have duty cycles of substantially 50%. Memory circuit 24 receives the CLKOUT signal and the bCLKOUT signal to transfer data into and/or out of memory circuit 24.

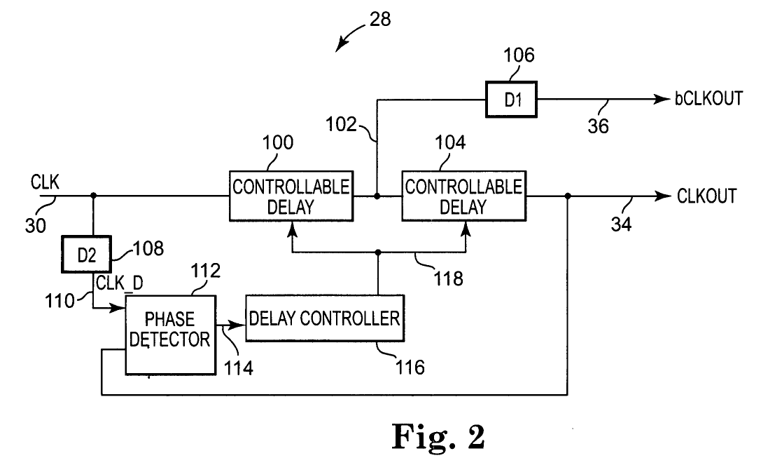

FIG. 2 is a block diagram illustrating one embodiment of duty cycle corrector 28. Duty cycle corrector 28 includes controllable delays 100 and 104, fixed delays D1 106 and D2 108, phase detector 112, and delay controller 116. The input of controllable delay 100 and the input of fixed delay D2 108 receive the CLK signal on CLK signal path 30. The output of fixed delay D2 108 is electrically coupled to a first input of phase detector 112 through delayed clock (CLK_D) signal path 110. The output of phase detector 112 is electrically coupled to the input of delay controller 116 through signal path 114. The output of delay controller 116 is electrically coupled to the control input of controllable delay 100 and the control input of controllable delay 104 through signal path 118. The output of controllable delay 100 is electrically coupled to the input of fixed delay D1 106 and the input of controllable delay 104 through signal path 102. The output of fixed delay D1 106 provides the bCLKOUT signal on bCLKOUT signal path 36. The output of controllable delay 104 is electrically coupled to a second input of phase detector 112 and provides the CLKOUT signal on CLKOUT signal path 34.

In one embodiment, the delay of fixed delay D2 108 is two times the delay of fixed delay D1 106. Fixed delay D1 106 and fixed delay D2 108 enable duty cycle corrector 28 to operate at high clock frequencies, such as clock frequencies above 500 MHz. Fixed delay D1 106 and fixed delay D2 108 prevent the intrinsic delay within duty cycle corrector 28 from preventing high clock frequency operation by delaying the CLK signal input to phase detector 112. In particular, fixed delay D1 106 and fixed delay D2 108 prevent the intrinsic delay through controllable delay 100 and controllable delay 104 from preventing high clock frequency operation of duty cycle corrector 28.

Fixed delay D2 108 delays the CLK signal on CLK signal path 30 to provide the CLK_D signal on CLK_D signal path 110. Controllable delay 100 delays the CLK signal on CLK signal path 30 to provide the signal on signal path 102. The delay of controllable delay 100 is selected based on the control signal input to controllable delay 100 on signal path 118. Controllable delay 100 is any suitable type of variable delay, such as a series of inverters switched by the control signal input. Fixed delay D1 106 delays the signal on signal path 102 to provide the bCLKOUT signal on bCLKOUT signal path 36. Controllable delay 104 delays the signal on signal path 102 to provide the CLKOUT signal on CLKOUT signal path 34. The delay of controllable delay 100 is selected based on the control signal input to controllable delay 110 on signal path 118. Controllable delay 100 is any suitable type of variable delay, such as a series of inverters switched by the control signal input. In one embodiment, controllable delay 104 is identical to controllable delay 100.

Phase detector 112 receives the CLK_D signal on CLK_D signal path 110 and the CLKOUT signal on CLKOUT signal path 34 to provide the signal on signal path 114. Phase detector 112 determines the phase difference between the CLK_D signal and the CLKOUT signal to provide a phase difference signal on signal path 114. Delay controller 116 receives the phase difference signal on signal path 114 to provide a control signal on signal path 118. Delay controller 116 provides the control signal based on the phase difference signal to adjust the delay of controllable delay 100 and the delay of controllable delay 104 such that the CLKOUT signal is phase locked to the CLK_D signal. In one embodiment, the delay of controllable delay 100 and the delay of controllable delay 104 are adjusted equally by delay controller 116.

In operation, the CLK signal is delayed by controllable delay 100 and fixed delay D1 106 to provide the bCLKOUT signal. The CLK signal is also delayed by controllable delay 100 and controllable delay 104 to provide the CLKOUT signal and an input to phase detector 112. The CLK signal is also delayed by fixed delay D2 108 to provide the CLK_D signal input to phase detector 112. The CLK_D signal and the CLKOUT signal inputs to phase detector 112 are compared to determine the phase difference between the CLK_D and the CLKOUT signals. The phase difference is passed to delay controller 116. Delay controller 116 adjusts the delay of controllable delay 100 and the delay of controllable delay 104 based on the phase difference to phase lock the CLKOUT signal to the CLK_D signal within one cycle of the CLK_D signal. The bCLKOUT signal is the inverse of the CLKOUT signal and leads the CLKOUT signal by one-half clock cycle. The duty cycle of the CLKOUT signal is approximately 50%, and the duty cycle of the bCLKOUT signal is approximately 50%.

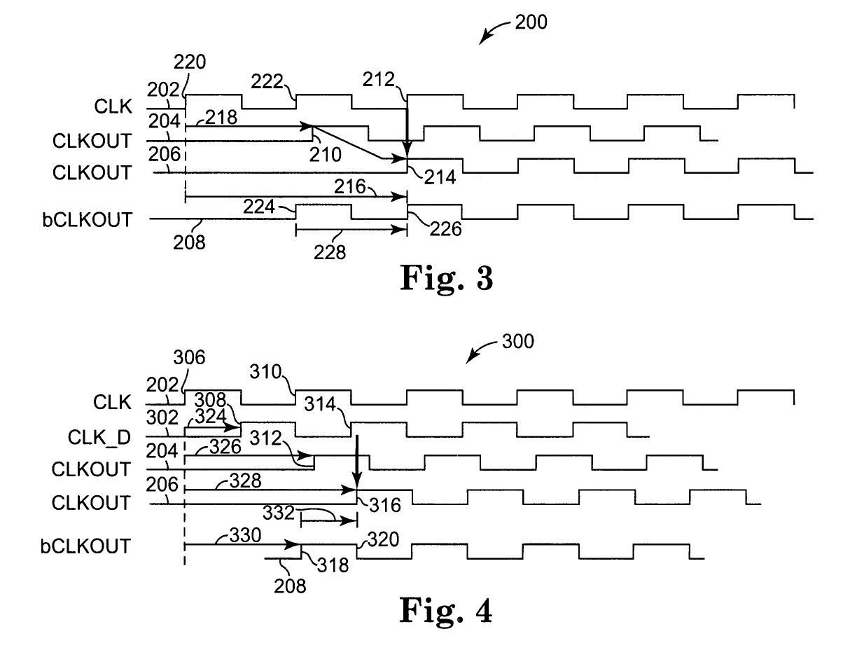

FIG. 3 is a timing diagram 200 illustrating one embodiment of the timing of signals for duty cycle corrector 28 without fixed delay D1 106 and fixed delay D2 108. Timing diagram 200 includes CLK signal 202 on CLK signal path 30, CLKOUT signal 204 on CLKOUT signal path 34, CLKOUT signal 206 on CLKOUT signal path 34, and bCLKOUT signal 208 on bCLKOUT signal path 36.

CLKOUT signal 204 indicates the intrinsic delay (tINC) of the CLK signal through controllable delay 100 and controllable delay 104 without any additional delay selected for controllable delay 100 and controllable delay 104. The intrinsic delay between rising edge 220 of CLK signal 202 and rising edge 210 of CLKOUT signal 204 is indicated at 218. The intrinsic delay through controllable delay 100 and controllable delay 104 is longer than one cycle of CLK signal 202 as indicated by rising edge 210 of CLKOUT signal 204 being provided after rising edge 222 of CLK signal 202. Rising edge 220 of CLK signal 202 is delayed by controllable delay 100 to provide rising edge 224 of bCLKOUT signal 208.

CLKOUT signal 206 is the CLKOUT signal once the CLKOUT signal is phase locked. In response to rising edge 210 of CLKOUT signal 204, phase detector 112 determines the phase difference between CLK signal 202 and CLKOUT signal 204. Phase detector 112 passes the phase difference to delay controller 116. Delay controller 116 adjusts the delay of controllable delay 100 and the delay of controllable delay 104 to phase lock CLKOUT signal 206 to CLK signal 220, such that rising edge 214 of CLKOUT signal 206 is aligned with rising edge 212 of CLK signal 202. Without fixed delay D1 106 and fixed delay D2 108, two cycles of CLK signal 202 indicated at 216 are used to phase lock CLKOUT signal 206 to CLK signal 202. With two cycles of CLK signal 202 used to phase lock CLKOUT signal 206 to CLK signal 202, bCLKOUT signal 208 leads CLKOUT signal 206 by one cycle as indicated at 228 between rising edge 224 and rising edge 226. Therefore, duty cycle corrector 28 fails without fixed delay D1 106 and fixed delay D2 108 since CLKOUT 206 and bCLKOUT 208 are in phase.

FIG. 4 is a timing diagram 300 illustrating one embodiment of the timing of signals for duty cycle corrector 28 with fixed delay D1 106 and fixed delay D2 108. In one embodiment, the delay of fixed delay D2 108 equals approximately two times the delay of fixed delay D1 106. Timing diagram 300 includes CLK signal 202 on CLK signal path 30, CLK_D signal 302 on CLK_D signal path 110, CLKOUT signal 204 on CLKOUT signal path 34, CLKOUT signal 206 on CLKOUT signal path 34, and bCLKOUT signal 208 on bCLKOUT signal path 36.

Rising edge 306 of CLK signal 202 is delayed by fixed delay D2 108 to provide rising edge 308 of CLK_D signal 302 as indicated at 324. In one embodiment, fixed delay D2 108 delays CLK signal 202 by one half cycle of CLK signal 202. CLKOUT signal 204 indicates the intrinsic delay (tINC) of the CLK signal through controllable delay 100 and controllable delay 104 without any additional delay selected for controllable delay 100 and controllable delay 104. The intrinsic delay between rising edge 306 of CLK signal 202 and rising edge 312 of CLKOUT signal 204 is indicated at 326. The intrinsic delay through controllable delay 100 and controllable delay 104 is longer than one cycle of CLK signal 202 as indicated by rising edge 312 of CLKOUT signal 204 being provided after rising edge 310 of CLK signal 202. The intrinsic delay indicated at 326 is similar to the intrinsic delay indicated at 218 in FIG. 3.

CLKOUT signal 206 is the CLKOUT signal once the CLKOUT signal is phase locked. In response to rising edge 312 of CLKOUT signal 204, phase detector 112 determines the phase difference between CLK_D signal 302 and CLKOUT signal 204. Phase detector 112 passes the phase difference to delay controller 116. Delay controller 116 adjusts the delay of controllable delay 100 and the delay of controllable delay 104 to phase lock CLKOUT signal 206 to CLK_D signal 302, such that rising edge 316 of CLKOUT signal 206 is aligned with rising edge 314 of CLK_D signal 302. With fixed delay D1 106 and fixed delay D2 108, one cycle of CLK_D signal 302 is used to phase lock CLKOUT signal 206 to CLK_D signal 302. With one cycle of CLK_D signal 302 used to phase lock CLKOUT signal 206 to CLK_D signal 302, bCLKOUT signal 208 is the inverse of CLKOUT signal 206 and duty cycle corrector 28 does not fail.

Rising edge 316 of CLKOUT signal 206 is delayed from rising edge 306 of CLK signal 202 by the delay through fixed delay D2 108 plus one cycle of CLK signal 202 as indicated at 328. Rising edge 318 of bCLKOUT signal 208 is delayed from rising edge 306 of CLK signal 202 by the delay through the controllable delay 100 and the delay through fixed delay D1 106 as indicated at 330. In one embodiment, the delay through controllable delay 100 equals the delay through fixed delay D1 106 plus one half cycle of CLK signal 306. Therefore, rising edge 318 of bCLKOUT signal 208 is delayed from rising edge 306 of CLK signal 202 by two times the delay through fixed delay D1 106 plus one half cycle of CLK signal 202. The bCLKOUT signal 208 is the inverse of CLKOUT signal 206 such that rising edge 316 of CLKOUT signal 206 is aligned with falling edge 320 of bCLKOUT signal 208, and bCLKOUT signal 208 leads CLKOUT signal 206 by one half cycle of CLKOUT signal 206 as indicated at 332.

Embodiments of the present invention provide a duty cycle corrector including additional fixed delay D1 and additional fixed delay D2. Additional fixed delay D1 and additional fixed delay D2 enable the duty cycle corrector to phase lock an internal clock signal to an external clock signal at high clock frequencies such that the duty cycle corrector does not fail. In addition, the duty cycle of the internal clock signal is approximately 50%, and the duty cycle of the inverted internal clock signal is approximately 50%.

What is claimed is:

1. A duty cycle corrector comprising:
a first controllable delay configured to delay a first signal to provide a second signal;
a second controllable delay configured to delay the second signal to provide a third signal;
a first fixed delay configured to delay the second signal to provide a fourth signal;
a second fixed delay configured to delay the first signal to provide a fifth signal; and
a circuit configured to adjust the first controllable delay and the second controllable delay to phase lock the third signal to the fifth signal.

2. The duty cycle corrector of claim 1, wherein the circuit comprises a phase detector configured to determine a phase difference between the third signal and the fifth signal for adjusting the first controllable delay and the second controllable delay.

3. The duty cycle corrector of claim 2, wherein the circuit comprises a delay controller configured to adjust the first controllable delay and the second controllable delay based on the phase difference.

4. The duty cycle corrector of claim 1, wherein a delay of the second fixed delay is twice as long as a delay of the first fixed delay.

5. The duty cycle corrector of claim 1, wherein a duty cycle of the third signal is approximately 50%.

6. A duty cycle corrector for a memory comprising:
a first controllable delay configured to delay a first clock signal to provide a second clock signal;
a second controllable delay configured to delay the second clock signal to provide a third clock signal;
a first fixed delay configured to delay the second clock signal to provide a fourth clock signal;
a second fixed delay configured to delay the first clock signal to provide a fifth clock signal;
a phase detector configured to determine a phase difference between the fifth clock signal and the third clock signal; and
a delay controller configured to adjust the first controllable delay and the second controllable delay based on the phase difference,
wherein the third clock signal is phase locked to the fifth clock signal within one cycle of the fifth clock signal, and
wherein the third clock signal is the inverse of the fourth clock signal.

7. The duty cycle corrector of claim 6, wherein the third clock signal is in phase with the first clock signal.

8. The duty cycle corrector of claim 6, wherein an intrinsic delay of the first controllable delay equals approximately a delay of the first fixed delay plus one half a cycle of the first clock signal, and wherein an intrinsic delay of the second controllable delay equals approximately the delay of the first fixed delay plus one half the cycle of the first clock signal.

9. The duty cycle corrector of claim 6, wherein a delay of the second fixed delay is approximately two times a delay of the first fixed delay.

10. The duty cycle corrector of claim 6, wherein the delay controller is configured to adjust the first controllable delay and the second controllable delay equally.

11. The duty cycle corrector of claim 6, wherein the third clock signal is used to transfer data into and out of the memory.

12. A memory comprising:
means for delaying an external clock signal to provide a first delayed external clock signal;
means for delaying the external clock signal to provide a second delayed external clock signal;
means for delaying the first delayed external clock signal to provide an internal clock signal;
means for delaying the first delayed external clock signal to provide an inverted internal clock signal; and
means for phase locking the internal clock signal to the second delayed external clock signal.

13. The memory of claim 12, wherein the memory comprises a dynamic random access memory.

14. The memory of claim 12, wherein the means for delaying the external clock signal to provide the first delayed external clock signal comprises means for selectively delaying the external clock signal to provide the first delayed external clock signal.

15. The memory of claim 12, wherein the means for delaying the first delayed external clock signal to provide the internal clock signal comprises means for selectively delaying the first delayed external clock signal to provide the internal clock signal.

16. The memory of claim 12, wherein the means for delaying the external clock signal to provide the second delayed external clock signal comprises a first fixed delay,
wherein the means for delaying the first external clock signal to provide the inverted internal clock signal comprises a second fixed delay, and
wherein the first fixed delay is approximately two times the second fixed delay.

17. A method for correcting the duty cycle of a first signal, the method comprising:
delaying the first signal a first selectable time to provide a second signal;
delaying the second signal a second selectable time to provide a third signal;
delaying the first signal a first fixed time to provide a fourth signal;
delaying the second signal a second fixed time to provide a fifth signal; and
adjusting the first selectable time and the second selectable time to phase lock the third signal to the fourth signal.

18. The method of claim 17, wherein delaying the second signal the second selectable time comprises delaying the second signal the second selectable time to provide the third signal having a duty cycle of approximately 50%.

19. The method of claim 17, wherein delaying the second signal the second fixed time comprises delaying the second signal the second fixed time to provide the fifth signal having a duty cycle of approximately 50%.

20. The method of claim 17, wherein delaying the second signal the second selectable time comprises delaying the second signal the second selectable time to provide the third signal inverse to the fifth signal.

21. The method of claim 17, wherein delaying the second signal the second fixed time comprises delaying the second signal a second fixed time one half the first fixed time.

22. A method for correcting the duty cycle of a clock signal in a memory, the method comprising:
delaying an external clock signal through a first controllable delay to provide a first delayed external clock signal;
delaying the first delayed external clock signal through a second controllable delay to provide an internal clock signal;
delaying the first delayed external clock signal through a first fixed delay to provide an inverted internal clock signal;
delaying the external clock signal through a second fixed delay to provide a second delayed external clock signal; and
controlling the first controllable delay and the second controllable delay based on a phase difference between the internal clock signal and the second delayed external clock signal to phase lock the internal clock signal to the second delayed external clock signal.

23. The method of claim 22, wherein delaying the first delayed external clock signal through the second controllable delay comprises delaying the first delayed external clock signal through the second controllable delay to provide the internal clock signal having a duty cycle of approximately 50%.

24. The method of claim 22, wherein delaying the first delayed external clock signal through the first fixed delay comprises delaying the first delayed external clock signal through the first fixed delay to provide the inverted internal clock signal having a duty cycle of approximately 50%.

25. The method of claim 22, wherein controlling the first controllable delay and the second controllable delay comprises controlling the first controllable delay and the second controllable delay based on the phase difference between the internal clock signal and the second delayed external clock signal to phase lock the internal clock signal to the second delayed external clock signal within one clock cycle of the second delayed external clock signal.

26. The method of claim 22, wherein delaying the external clock signal through the second fixed delay comprises delaying the external clock signal through a second fixed delay two times the first fixed delay.
